(19) United States
(12) Patent Application Publication
(10) Pub. No.: US 2011/0266643 A1
(43) Pub. Date: Nov. 3, 2011

(54) Solid state neutron detector

(76) Inventors: Michael G. Engelmann, Pukalani, HI (US); Peter Martin, Kahului, HI (US)

(21) Appl. No.: 13/066,951

(22) Filed: Apr. 28, 2011

Related U.S. Application Data
(60) Provisional application No. 61/343,488, filed on Apr. 28, 2010.

(51) Int. Cl. H01L 31/117

(52) U.S. Cl. 257/429; 257/E31.087

(57) ABSTRACT

A low-cost device for the detection of thermal neutrons. Thin layers of a material chosen for high absorption of neutrons with a corresponding release of ionizing particles are stacked in a multi-layer structure interleaved with thin layers of hydrogenated amorphous silicon PIN diodes. Some of the neutrons passing into the stack are absorbed in the neutron absorbing material producing neutron reactions with the release of high energy ionizing particles. These high-energy ionizing particles pass out of the neutron absorbing layers into the PIN diode layers creating electron-hole pairs in the intrinsic (I) layers of the diode layers; the electrons and holes are detected by the PIN diodes.

### CROSS REFERENCE TO RELATED APPLICATIONS

This application claims the benefit of Provisional Patent Application Ser. No. 61/343,488 filed Apr. 28, 2010.

### FIELD OF THE INVENTION

This invention relates to neutron detectors and in particular to solid state neutron detectors.

### BACKGROUND OF THE INVENTION

Neutron detectors are used for monitoring of cargo containers and vehicles for nuclear weapons because neutrons are emitted by radiological materials of interest such as plutonium and they are difficult to shield. Neutron detectors are also used in other applications such as medical diagnostics, oil and gas exploration; and scientific research. The prior art includes several different types of neutron detectors, as described here.

### Helium-3 Tube Detectors

Helium-3 (³He) tube detectors are the dominant technology used for neutron detection due to their superior sensitivity to neutrons. These detectors are also relatively insensitive to high energy electromagnetic (gamma) radiation thus enabling very low false positive detection capability for neutrons. ³He detectors consist of a stainless steel or aluminum tube cathode filled with a gas mixture that contains ³He. An anode wire is located at the center of the tube and a voltage, typically 1000 V, is applied from the cathode to the anode. An incident neutron interacts with an ³He atom, producing a proton and tritium atom that move in opposite directions with 764 KeV kinetic energy, ionizing the surrounding gas. The liberated electrons are collected at the anode producing a detectable pulse. ³He proportional tubes typically vary in diameter up to 50 mm and in length up to 2 meters. The gas is usually pressurized in the tube to increase the ³He density with pressures ranging from 2 to 20 atmospheres. Hand held detectors have more typical dimensions of 25 mm diameter and 10 to 20 cm active length and pressures up to 4 atmospheres.

### Boron Tri-Fluoride and Boron Lined Tube Detectors

Boron tri-fluoride (BF₃) proportional counters consist of a stainless steel or aluminum tube cathode filled with a gas mixture that contains BF₃. The boron is commonly enriched to >90% boron-10 (¹⁰B). An anode wire is located in the center of the tube and a voltage, typically 3000V, is applied from the cathode to the anode. An incident neutron interacts with a ¹⁰BF₃ molecule, producing an alpha and ionized ⁷Li particle that move in opposite directions, ionizing the surrounding gas. The liberated electrons are collected at the anode producing a detectable pulse. ¹⁰BF₃ proportional tubes come in similar sizes as the ³He tubes, but typically have ⅕ the sensitivity of the ³He tubes and relatively poor gamma insensitivity. The ¹⁰BF₃ gas is toxic and each neutron reaction produces three fluorine atoms that are highly corrosive; this poses manufacturing and operational risks for this technology.

Boron-lined proportional counters incorporate the enriched ¹⁰B as a solid film coating on the interior tube surface area. Otherwise, the geometry is the same as for the gas filled proportional counters. The tube is filled with two to three atmospheres of buffer gas (e.g. argon gas). An incident neutron interacts with a ¹⁰B, producing an alpha and ionized ⁷Li particle that move in opposite directions, ionizing the surrounding gas. The liberated electrons are collected at the anode producing a detectable pulse. ¹⁰B line tubes typically have 1/7 the sensitivity of the ³He tubes and relatively poor gamma insensitivity.

### Solid State Neutron Detectors

Solid state neutron detectors using crystalline semiconductor materials have been demonstrated; specifically, a ¹⁰B layer coated on a GaAs p-n photodiode to provide 4% intrinsic efficiency for neutron detection. However, crystalline semiconductor neutron detectors cannot be stacked to provide higher neutron detection efficiency. Fabrication techniques involving the etching of trenches in the semiconductor photodiode and backfilling with ¹⁰B material are under development to increase the neutron detection efficiency of the single ¹⁰B layer devices.

### Other Neutron Detection Methods

Other methods of neutron detection include neutron sensitive scintillating fiber detectors based on ⁶Li-loaded glass, ¹⁰B-loaded plastic; and ⁶Li-coated or ¹⁰B-coated optical fibers. The interaction of the neutron either a ⁶Li or ¹⁰B atom produces particles and gamma radiation that produce visible light. The visible light travels down the optical fiber to a detector, typically a photo-multiplier tube (PMT). The relatively high cost of these technologies has resulted in limited deployment.

What is needed in a low-cost neutron detector that can justify substantially greater deployment.

### SUMMARY OF THE INVENTION

This invention provides a low-cost device for the detection of thermal neutrons. Thin layers of a material chosen for high absorption of neutrons with a corresponding release of ionizing particles are stacked in a multi-layer structure interleaved with thin layers of hydrogenated amorphous silicon PIN diodes. Some of the neutrons passing into the stack are absorbed in the neutron absorbing material producing neutron reactions with the release of high energy ionizing particles. These high-energy ionizing particles pass out of the neutron absorbing layers into the PIN diode layers creating electron-hole pairs in the intrinsic (I) layers of the diode layers; the electrons and holes are detected by the PIN diodes. These stacks can be mass-produced at very low cost utilizing integrated circuit fabrication processes. A preferred neutron absorbing material is boron 10 (¹⁰B) which has a high neutron capture cross section and splits into a high-energy alpha particle and a high-energy lithium 7 isotope each of which can produce ionization in the hydrogenated amorphous silicon PIN diodes.

Preferred embodiments utilize boron enriched in the boron-10 (¹⁰B) isotope. When a neutron passes through the detector, the interaction of the neutrons with the ¹⁰B isotopes generates ionizing alpha particles and lithium 7 particles to produce electron hole pairs in the intrinsic layers of the PIN diodes. Preferred embodiments include 5, 10, 15 and 22 layer stacks. The stacked structure can provide very high intrinsic efficiency (greater than 80% for a twenty-two ¹⁰B layer stack) for thermal neutron detection.

The multiple diodes are electrically combined in parallel to provide the total neutron-induced signal current thus enabling a low overall bias voltage (≈10 V) for the detector. The a-Si:H diodes have a very low cross section for gamma radiation and discrimination circuitry is used to further reduce detection of incident gamma rays. Fast neutrons (with energies greater than 1 eV) can be detected by enclosing the thermal neutron detector in a neutron moderator material (polyethylene, for example) that slows the fast neutrons to thermal velocities.

A key element of invention is the use of hydrogenated amorphous silicon (a-Si:H) for the interleaved diodes. The disordered structure of a-Si:H provides an elastic property to the semiconductor material, relative to crystalline semiconductor materials. This elastic property enables the stacking of a plurality of ¹⁰B layers interleaved with the a-Si:H diodes by reducing the interfacial stress between layers. In addition, the a-Si:H diodes can be deposited directly onto metal electrode substrate material. Several other isotopes are available that produce high-energy ionizing particles with the absorption of neutrons and can be used in the place of the boron-10 isotope.

### BRIEF DESCRIPTION OF THE DRAWINGS

FIG. 1 is cross-sectional diagram showing a neutron detector comprising one ¹⁰B layer interleaved between two adjacent hydrogenated amorphous silicon (a-Si:H) diodes.

FIG. 2 is a graph showing the intrinsic efficiency for detection of neutrons versus ¹⁰B layer thickness for the neutron detector displayed in FIG. 1 (solid line).

FIG. 3 is an electrical schematic diagram showing the single ¹⁰B layer neutron detector, the two adjacent diodes electrically connected in parallel, and the electrical circuitry to detect neutrons.

FIG. 4 shows the voltage V_{A} at point A as a function of time during a neutron detection event.

FIG. 5 is cross-sectional diagram showing the preferred embodiment of a solid state neutron detector comprising five ¹⁰B layers interleaved between six adjacent hydrogenated amorphous silicon (a-Si:H) diodes.

FIG. 6 is a graph showing the intrinsic efficiency for neutron detection in the stacked structure versus number of ¹⁰B layers.

FIG. 7 is an electrical schematic drawing showing the preferred five ¹⁰B layer neutron detector, the six adjacent diodes electrically connected in parallel, and the preferred electrical circuitry to detect neutrons.

FIG. 8 is a graph showing the capacitance of a five ¹⁰B-layer neutron detector versus areal size.

FIG. 9 is a graph showing the characteristic time constant of a five ¹⁰B-layer neutron detector versus areal size.

FIG. 10 shows the preferred detector layout and preferred electrical circuitry for the thermal neutron detector.

FIG. 11 shows a graph of the absorption probability of a gamma photon versus the energy of the gamma photon, for a five ¹⁰B layer neutron detector.

FIG. 12 shows a graph of the range of an energetic electron in a-Si:H versus the kinetic energy of the electron.

FIG. 13 shows a graph of the maximum detectable energy from the absorption of a gamma photon as a function of initial gamma ray energy, for a five ¹⁰B layer neutron detector.

FIG. 14 shows a neutron spectrometer that incorporates the preferred thermal neutron detector. Thermal neutrons are captured and detected in the first layer. Fast neutrons of increasing energy are captured and detected in subsequent layers.

### DETAILED DESCRIPTION OF PREFERRED EMBODIMENTS

### Single ¹⁰B Layer Neutron Detector

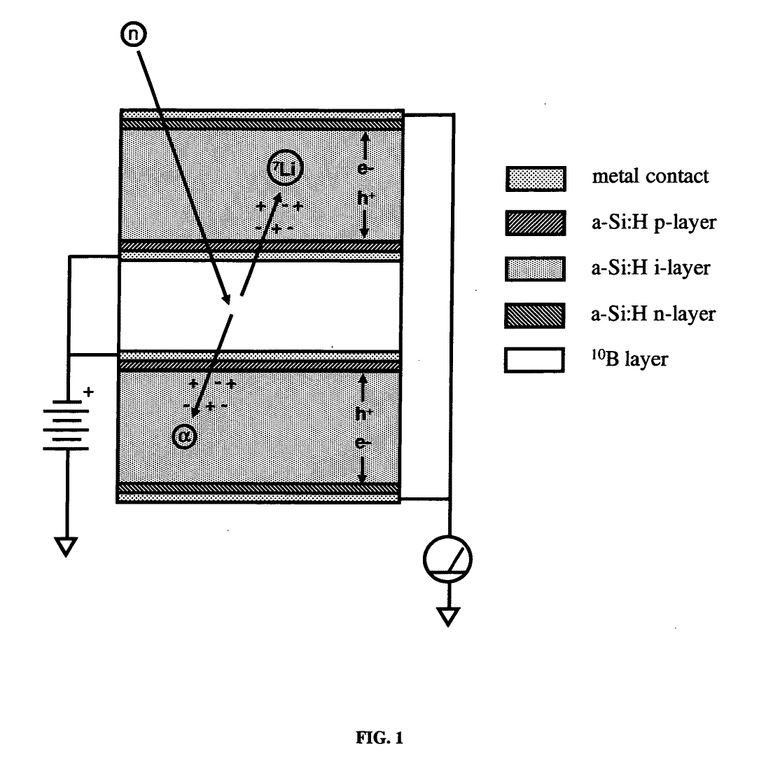

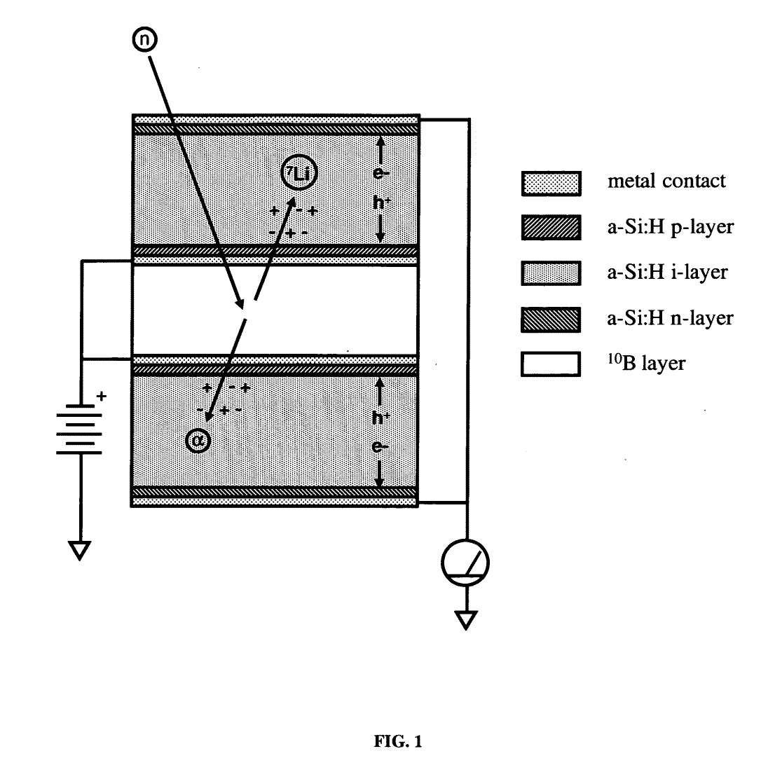

FIG. 1 shows a cross-sectional diagram of the interleaved between two hydrogenated amorphous silicon (a-Si:H) PIN diodes. When a neutron passes through the detector, the interaction of the neutron with a boron atom (¹⁰B) generates ionizing alpha and lithium particles that move in opposite directions through the ¹⁰B layers and into the adjacent a-Si:H diodes. The kinetic energies of the alpha and/or lithium particles are converted to a large number of liberated electron/hole pairs in the a-Si:H diodes. The liberated electric charge is collected by electric circuitry thereby producing a charge pulse corresponding to the detected neutron.

Amorphous silicon cannot detect neutrons directly. Therefore, a neutron absorbing layer is used to capture the neutron and emit one or more ionizing particles that may then be detected in adjacent a-Si:H diodes. Several candidates for this layer with large neutron capture cross-sections include Lithium (⁷Li), Boron (¹⁰B), and Gadolinium (Gd). The preferred embodiment is a ¹⁰B layer because it offers a large capture cross-section for thermal neutrons (3840 barns) and rapid emission of moderate energy ionizing alpha particles at 1-2 MeV. ¹⁰B occurs with a natural abundance of 19.9%, but this may be increased to nearly 100% by enrichment. In addition, ¹⁰B has a relatively low atomic number (Z=5) thus enabling relatively high insensitivity to high energy electromagnetic (gamma) radiation. Another key advantage to using a ¹⁰B containing layer is that thin film layers may be grown by conventional semiconductor processes. Neutrons interact with ¹⁰B via the ¹⁰B(n,α)⁷Li reaction:

$${}^{10} B + n \to \{ \begin{matrix}{}^{7} Li * ( 840 keV ) + α ( 1.470 MeV ) & ( 94 \% ) \\ {}^{7} Li ( 1.015 MeV ) + α ( 1.777 MeV ) & ( 6 \% )\end{matrix}$$

The ⁷Li produced in the first reaction path begins in the first excited state, but rapidly drops to the ground state via the emission of a 480 KeV gamma ray. The two products (⁷Li and a) of each reaction are emitted in opposite directions.

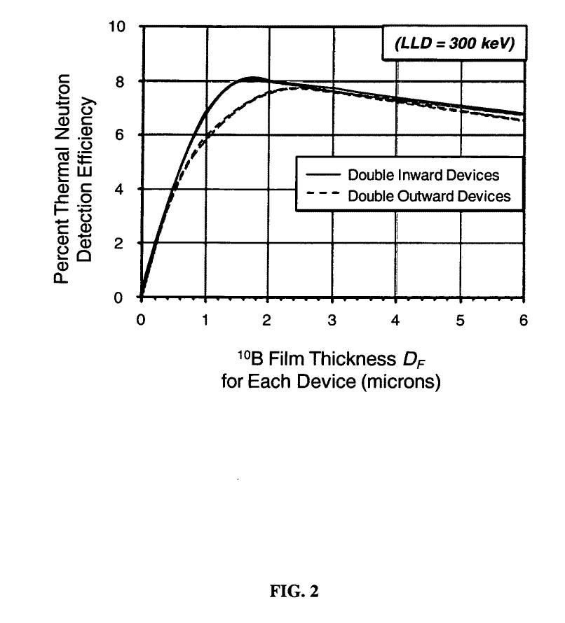

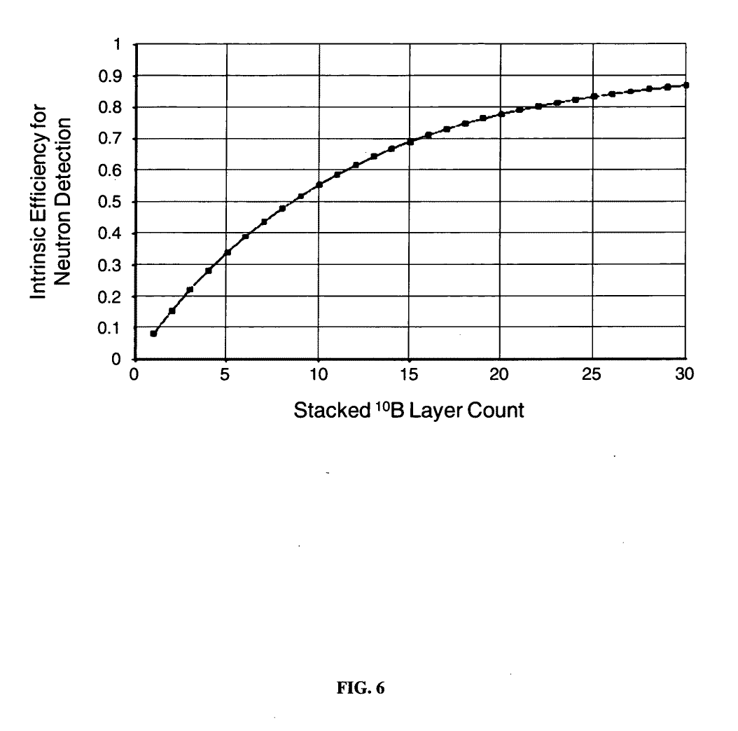

FIG. 2 shows the intrinsic efficiency for neutron detection for the single ¹⁰B layer neutron detector versus ¹⁰B layer thickness; “intrinsic efficiency” is defined as the number of detected neutrons divided by the number of neutrons incident on the detector [D. S. McGregor et. al., Nuclear Instruments and Methods, A500 (2003) pp. 272-308]. The ¹⁰B layer must be thick enough to absorb an appreciable percentage of incident thermal neutrons, and also thin enough to enable the majority of the emitted alpha and/or lithium particles to traverse to the adjacent a-Si:H diode layers where they create a large number of electron-hole pairs. The average range in the ¹⁰B layer is 3.6 microns for a 1.470 MeV alpha particle and 1.6 microns for an 840 keV ⁷Li particle. In addition, each neutron capture event results in the alpha/lithium particle pairs being emitted, in opposite directions, randomly over all angles; therefore requiring integration of the emission process over 4π steradians. FIG. 2 shows that the optimal thickness is 1.6 microns for the ¹⁰B layer; this thickness provides an intrinsic efficiency of about 8% for thermal neutron detection. Greater efficiencies are produced by stacking the layers as indicated in FIG. 6 and as will be explained below.

The thicknesses of the diode layers are determined based on the range of the ionizing particles in a-Si:H. Higher energy particles have a longer range within the a-Si:H material, so the characteristic range is calculated using the 1.470 MeV alpha particle of the most common reaction. The range of an alpha particle in a-Si:H is given by

$$R ( {E}_{0} ) = \frac{1}{λ {S}_{0}} ln ( \frac{{A}_{0} + {e}^{λ {E}_{0}}}{{A}_{0} + 1} )$$

where λ=0.2154 MeV⁻¹, S₀=497 MeV-cm, and A₀=5.47 [Ho Kyung et. al., Journal of the Korean Nuclear Society, Vol. 28, No. 4, pp 397-405, August 1996]. For a 1.47 MeV alpha particle, this yields a range of 5.23 μm. Therefore, the a-Si:H diodes must be at least 5 microns thick for maximum charge pair generation. The average ionizing energy required to generate an electron-hole pair in a-Si:H is 5 eV. The alpha and/or ionized lithium particle will, on average, still retain between 300 KeV-1 MeV of kinetic energy when it leaves the ¹⁰B layer and reaches the a-Si:H diode, therefore the particle will generate 60,000-200,000 electrons as it is stopped by the a-Si:H diode.

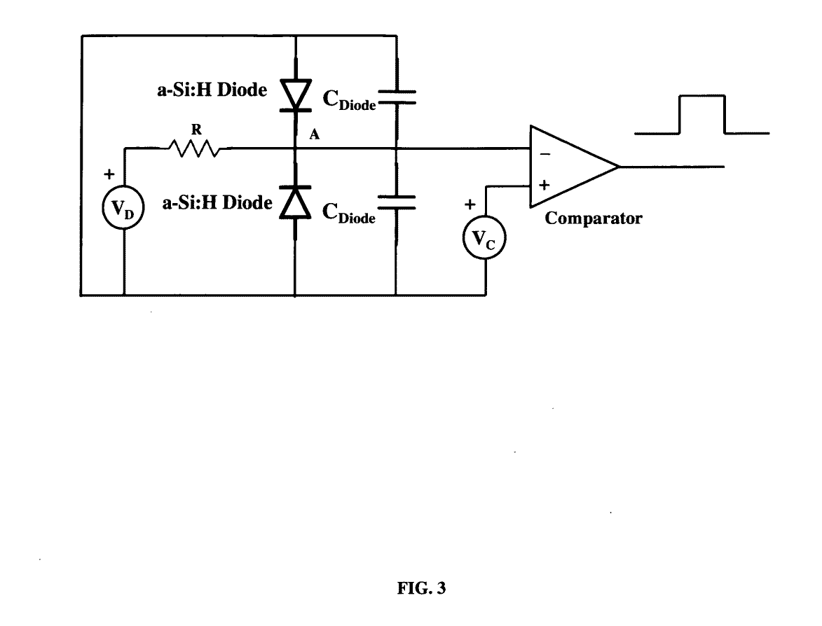

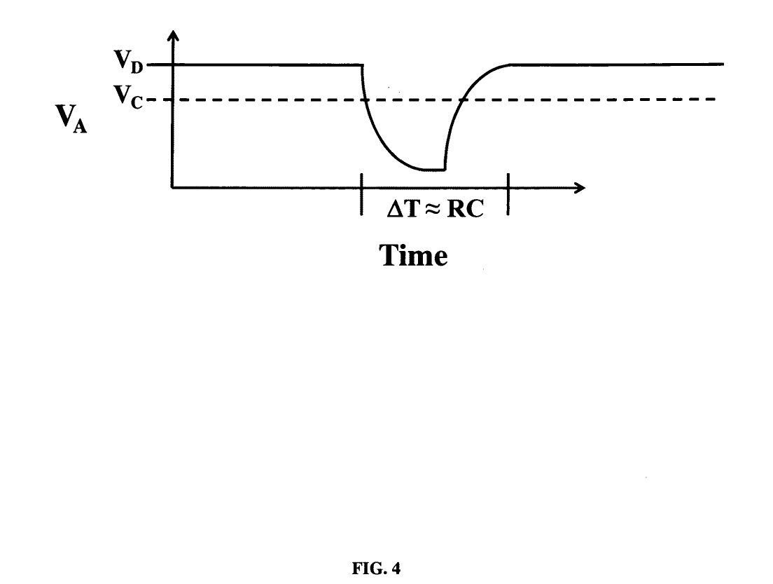

FIG. 3 displays an electrical schematic diagram of the single ¹⁰B layer neutron detector and the preferred electrical circuitry to detect neutrons. The two a-Si:H diodes in the neutron detector are electrically connected in parallel. In this configuration, an externally applied reverse bias voltage V_{D}≈10 Volts is required to fully deplete each diode and to produce an electric field (approximately 2 V/micron) across each diode. The a-Si:H diodes are shielded by incident visible light so that they do not produce electric photocurrent from the incident light. FIG. 4 shows the voltage V_{A} at point A as a function of time when a neutron is detected. The room temperature dark current density from these diodes is very low, less than 1×10⁻⁹ Amps/cm², when neutrons are not present in the detector, therefore the voltage drop across resistor R is essentially zero and the voltage at point A, V_{A}=V_{D}. The voltage V_{A} is compared to a comparator voltage V_{C} by a comparator. The voltage V_{C} is set so that V_{A}>V_{C} and the comparator output produces a digital “0” when no neutrons are present at the detector. When a neutron is incident on the detector, the liberated electric charge Q originating in the diodes due to a detected neutron creates a transient current I=Q/T where T=RC is the characteristic time constant of the circuit. The current I flows across resistor R for an approximate time period T=RC thus creating a transient voltage drop ΔV=IR across resistor R and the voltage at point A drops to V_{A}=V_{D}−ΔV=V_{D}−IR. The comparator voltage V_{C} is set so that V_{A}<V_{C} during the transient current flow and a digital “1” is produced at the comparator output, thus signaling the detection of a neutron. The preferred voltage V_{C} is approximately set so that the transient voltage V_{A} produced by electric charge liberated by a 300 KeV gamma photon incident on the diodes is equal to V_{c}, thus providing discrimination against low energy gamma radiation. Alternate embodiments for the comparator function include a comparator that incorporates positive feedback and therefore hysteresis, commonly known as a Schmitt trigger device. This will reduce the number of miscounted neutron events due to multiple flips of the comparator output during a single event measurement.

### First Preferred Embodiment

### Five ¹⁰B Layer Neutron Detector

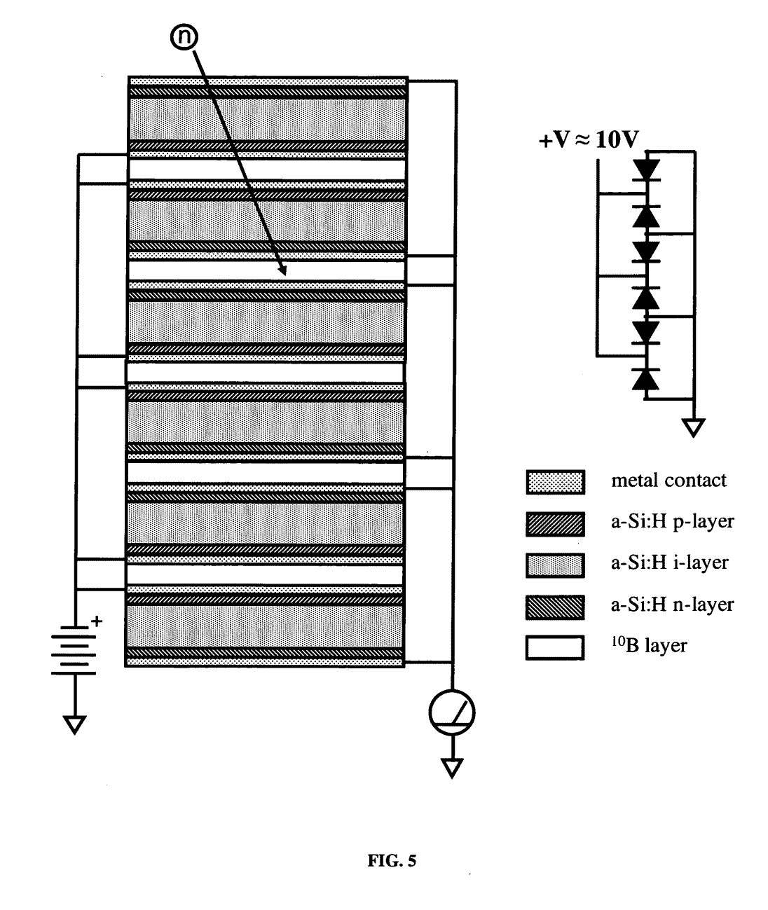

FIG. 5 shows a cross-sectional diagram of the preferred embodiment of the invention involving five ¹⁰B layers interleaved between six hydrogenated amorphous silicon (a-Si:H) PIN diodes. As a single neutron passes through the detector, it will have an eight percent probability of being absorbed in the first ¹⁰B layer, assuming a 1.6 micron thick layer of greater than 90% enriched ¹⁰B in the ¹⁰B layers. If the first ¹⁰B layer (N=1) does not absorb the neutron, then the other ¹⁰B layers (N=2, 3, 4, 5) will contribute to the total intrinsic efficiency P_{ABS}(N=5) according to the equation

P_{ABS}(N)=1−exp└−NP_{ABS,SINGLELAYER}┘

where P_{ABS,SINGLELAYER}=0.08 is the intrinsic efficiency for neutron detection in a single ¹⁰B layer device. FIG. 6 shows a graph of the intrinsic efficiency for detecting neutrons P_{ABS} (N) versus number of ¹⁰B layers N. FIG. 6 shows that the preferred embodiment has P_{ABS}(N=5)=34% intrinsic efficiency for detecting neutrons.

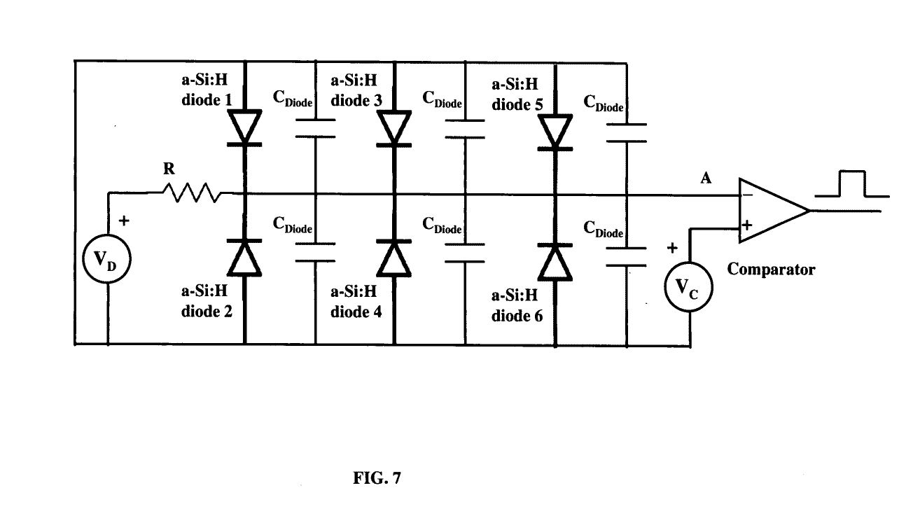

FIG. 7 displays an electrical schematic diagram of the five ¹⁰B layer neutron detector, including the preferred electrical circuitry to detect neutrons. The multiple a-Si:H diodes in the neutron detector are all electrically connected in parallel. In this configuration, an externally applied reverse bias voltage around V_{D}≈10 Volts is required to fully deplete each diode and to produce an electric field (approximately 2 V/micron) across each diode. The rest of the circuitry is substantially the same as for the single ¹⁰B layer neutron detector. The preferred embodiment incorporates a single a-Si:H diode between each ¹⁰B layer, therefore each diode can detector electrical charge resulting from neutron reactions in either ¹⁰B layer that is adjacent to the diode.

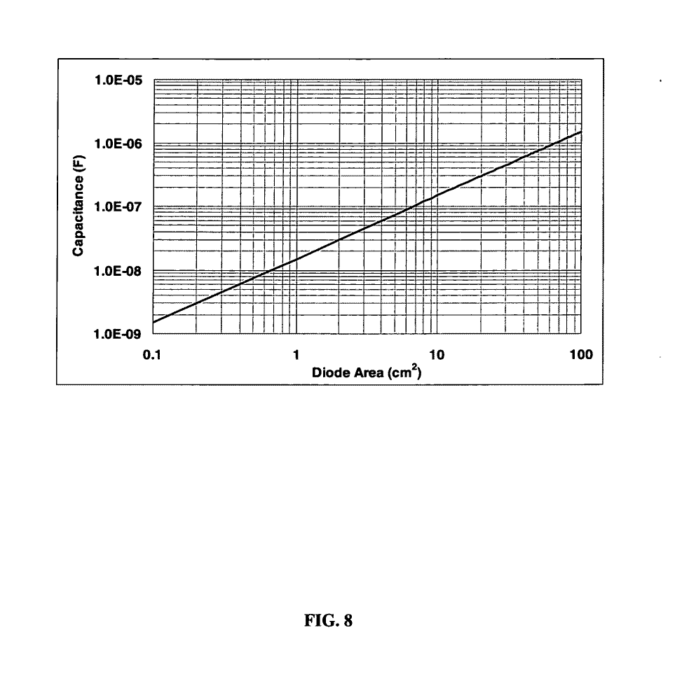

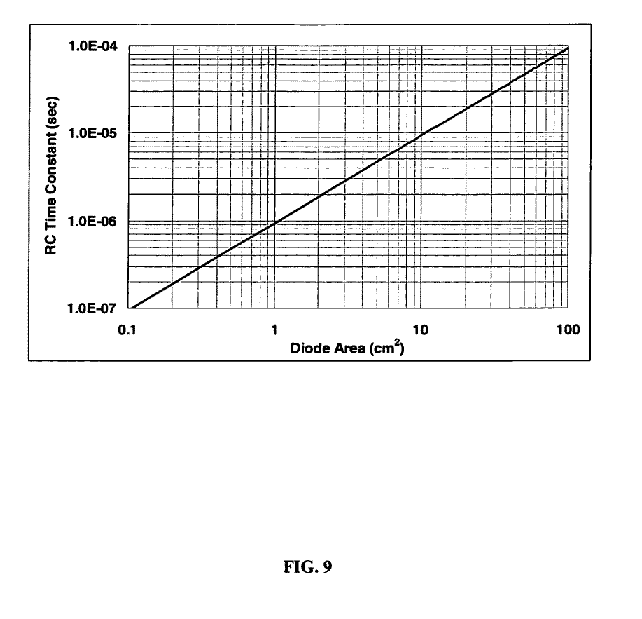

The electrical capacitance scales linearly with the area of the detector; and also scales linearly with the number of stacked a-Si:H diodes, since the capacitance of each diode in the stacked detector adds when connected in parallel. Therefore, the characteristic time constant T=RC grows linearly with the area and number of stacked diodes. FIG. 8 shows the capacitance of a five ¹⁰B-layer of the detector versus areal size, and FIG. 9 shows the characteristic time constant T=RC of this detector versus areal size. The graph in FIG. 9 assumes a series resistance of R=50Ω. The neutron detection rate is inversely proportional to the characteristic time constant of the detector.

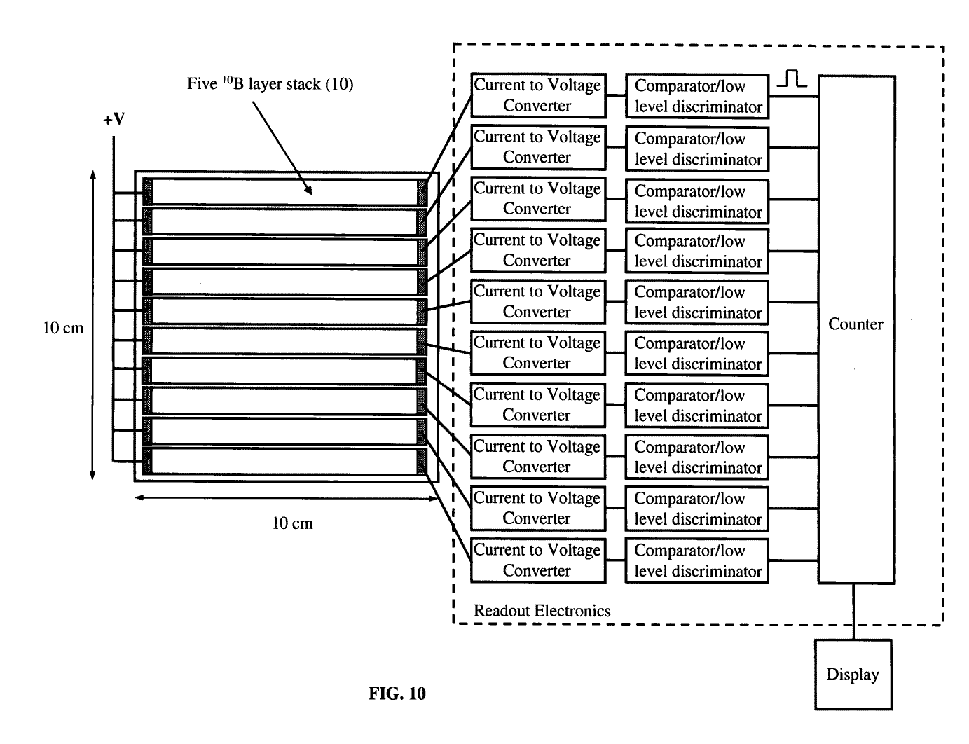

The preferred embodiment for the neutron detector, displayed in FIG. 10, consists of a one dimensional array of ten 10 cm×1 cm sub-detectors (each sub-detector consisting of a five ¹⁰B-layer monolithic stack). Each of the ten sub-detectors has its own readout circuitry as shown in FIG. 7. FIG. 8 and FIG. 9 show that each 10 cm×1 cm (10 cm²) sub-detector has a capacitance of 200 nF and an RC time constant of 10 μs. The preferred detector has approximately a 50 kHz detection rate capability for detecting neutrons. For comparison, a typical ³He tube detector has a 50 kHz neutron detection rate.

The fabrication the preferred embodiment of the neutron detector shown in FIG. 5, with five ¹⁰B-layers interleaved with six a-Si:H diodes, is accomplished by depositing the a-Si:H diode coating (approximately 5 microns thick) on a substrate (approximately 1 mm thick). Preferred substrate materials, including silicon and glass, have low cross section for neutron absorption. A ¹⁰B layer is then coated on top of the a-Si:H diode, followed by a second a-Si:H diode, etc., until the entire semiconductor stack is fabricated. The neutron detector area (10 cm×10 cm) is then divided into ten electrically isolated areas. Preferred electrical separation methods include the use of either stencil or photolithographic masks during deposition of the electrode layers; the a-Si:H diode layers do not require physical separation. Other electrical separation methods include post-deposition mechanical or laser scribing of the entire semiconductor stack. Preferred methods include the separation of the detector sections into strips with the electrodes for the multiple a-Si:H diodes accessible at the periphery of the substrate for external connection purposes. The description of the a-Si:H diode layers and ¹⁰B layers are presented here.

### Amorphous Silicon Diode Layers

The a-Si:H diode structures are fabricated using plasma enhanced chemical vapor deposition (PECVD). In this process, feedstock gases are delivered to a vacuum chamber and dissociated by means of a radio frequency (RF) plasma. When the gases are broken down, the resulting radicals react at all exposed surfaces, resulting in film growth. The preferred diode is deposited on a substrate, typically 1 mm thick, that has low absorption cross-section for neutrons, including high purity silicon wafer material, or high purity glass material. The first deposited layer for an a-Si:H P-I-N diode is a metal electrode layer such as titanium nitride (TiN), titanium tungsten (TiW), or indium tin oxide (ITO) layer, approximately 300 angstroms thick. The second deposited layer is a p-type doped layer that is produced using silane (SiH₄) gas with a small amount of diborane (B₂H₆) gas; this p-layer is typically 200 angstroms thick. The third deposited layer is the intrinsic amorphous silicon i-layer that is produced using silane gas; this layer is typically 5 microns thick. The fourth deposited layer is an n-type impurity doped layer that combines silane gas with a small amount of phosphine (PH₃) gas; this layer is typically 200 angstroms thick. The fifth deposited layer is a top electrode layer such as TiN, TiW, or ITO, approximately 300 angstroms thick.

Amorphous silicon diode structures of the types shown in FIG. 1 and FIG. 5 have great practical advantages over crystalline diode structures that are grown epitaxially on crystalline substrates. Crystalline diode structures, such as crystalline silicon, for example, feature a perfectly periodic spacing of atoms with very few impurities or crystal dislocations. These structures can be mathematically modeled. According to models typically utilized, the energy potential of each atom, combined with a wave representation of the mobile charges, results in an energy band gap between the valence and conduction bands. Incident photons provide the energy to elevate the electron energy from the valence band to the conduction band, thereby creating mobile charges. The near perfect order of the crystalline semiconductor, and relative absence of impurities or dislocations, results in a very low density of states in the forbidden energy bandgap and a high mobility of charges. The addition of p and n dopant layers provides PN or PIN photodiode structures with spatial depletion regions that permit electrical separation of liberated electron-hole pairs produced by incident massive particles. The bandgap also enables suppression of thermally generated dark current noise that ultimately limits the detection performance.

A PIN diode structure fabricated from hydrogenated amorphous silicon (a-Si:H) has similar electrical charge generation and collection properties as a crystalline silicon diode. The amorphous P, I, and N layers feature a disordered, but somewhat periodic, spacing of the silicon atoms; these atoms are surrounded by a plurality of hydrogen atoms and held together essentially by a large network of hydrogen bonds. The bulk semiconductor properties arise from averaging the microscopic features of the diode structure. The periodicity of the silicon atoms in the amorphous diode has enough definition so that amorphous semiconductor material has a forbidden energy bandgap separating the conduction and valence bands, and a spatial depletion region primarily in the I-layer. The forbidden energy bandgap in an amorphous material tends to feature a much larger density of energy states than in a crystalline semiconductor material due to the amorphous nature of the material. This leads to increased dark current and lower mobility of charges in an amorphous diode material. However, these material properties can be controlled in an a-Si:H diode to the level required for a high performance neutron detector.

The major practical advantage of a-Si:H diode structures involves the elastic nature of the material. The a-Si:H coating can gracefully incur much larger stresses because the silicon atoms are imbedded in a sea of hydrogen atoms; the hydrogen bonds provide material elasticity that enables the a-Si:H layers to be deposited directly onto non-crystalline materials, such as metal electrode materials, for example. In comparison, crystalline materials, fabricated using molecular beam epitaxy (MBE), require precise lattice matching to a flat underlying crystalline substrate, in order to control the interface stress. This elastic feature of a-Si:H diodes enables both the single ¹⁰B layer and the multiple ¹⁰B layer neutron detectors to be fabricated.

### Boron-10 (¹⁰B) Layers

The ¹⁰B layers are deposited in one of three methods; 1) evaporation of enriched ¹⁰B powder, 2) plasma enhanced chemical vapor deposition (PECVD) of enriched boron carbide (¹⁰BC₄) from enriched diborane (¹⁰B₂H₆) and methane (CH₄) precursors, which are already used for a-Si:H diode deposition, and 3) sputtering of enriched boron or boron carbide (BH₄) targets. ¹⁰B powder is commercially available and presently appears to be the most cost effective method for fabrication of the ¹⁰B layers. Semiconductor-grade ¹⁰B enriched diborane is commercially available for PECVD processing. ¹⁰B enriched boron and boron carbide sputter targets are also commercially available.

### Gamma Insensitivity of Neutron Detector

Neutron detectors require relatively high insensitivity to gamma radiation in order to reduce false positive neutron detections. The Applicant's neutron detector will be relatively insensitive to gamma radiation for three reasons:
(1) gamma radiation interacts much more efficiently with high Z materials than low Z materials, and that boron has a very low atomic number of Z=5,
(2) the ¹⁰B layers are not electrically associated with the detector output, and
(3) the silicon in the a-Si:H diodes has a relatively low atomic number of Z=14.

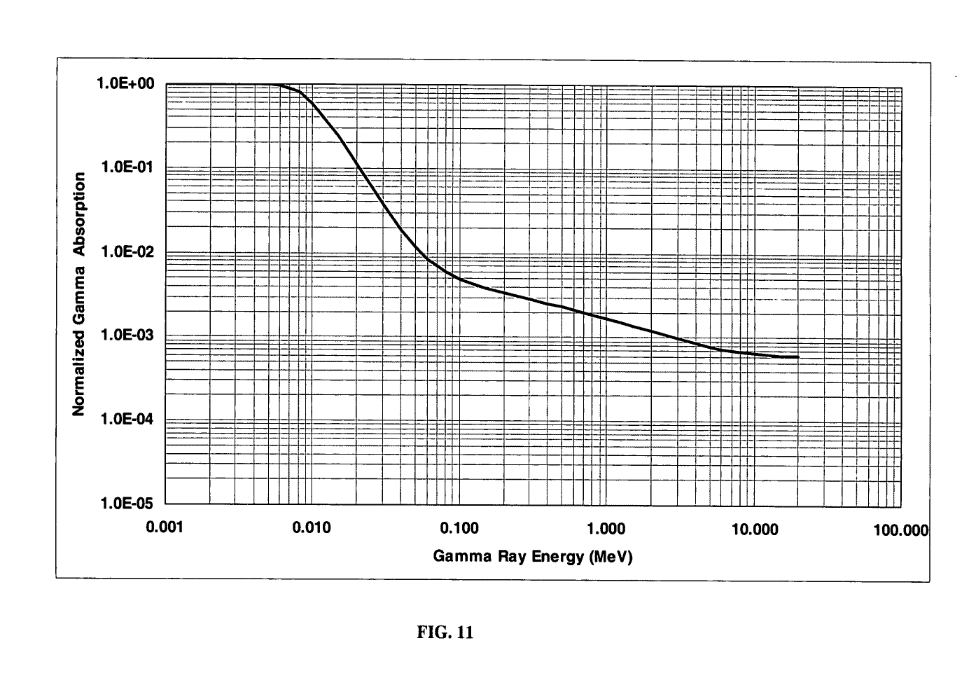

Gamma radiation interacts with a-Si:H by different processes depending on the energy of the gamma photon. At low energies up to about 100 KeV, the photoelectric effect is the dominant mode of interaction, where the gamma photon imparts its full energy to a single electron. At energies from about 100 KeV to several MeV, interactions are dominated by Compton scattering, where the gamma ray loses a fraction of its energy to an electron through an inelastic collision. At high energies above several MeV, the interaction is dominated by electron-positron pair production. FIG. 11 shows a graph of the absorption probability of a gamma photon versus the energy of the gamma photon, for a gamma photon incident on a twenty-two ¹⁰B layer neutron detector with a total thickness of 150 micron (1.6 micron thick ¹⁰B layers and 5 micron thick a-Si:H diodes).

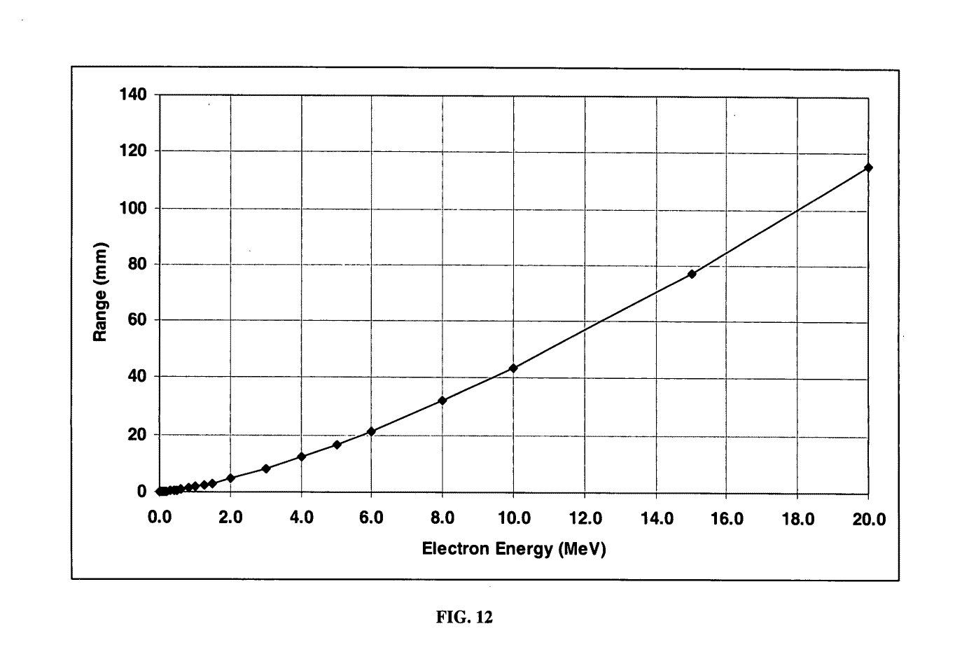

The product of the gamma photon interaction with a-Si:H is an energetic electron that will then ionize surrounding atoms as it moves through the a-Si:H material. The range R of an energetic electron in matter is dependent on the energy of the electron and the density of the material it is moving through. This range may be approximated using the following equation

$$R ( mm ) = 4 \times {10}^{3} \frac{{E}^{1.4} ( MeV )}{ρ ( kg \text{/} {m}^{3} )}$$

where E is the energy of the energetic electron and ρ is the density of the material [E. M. Hussein, Handbook on Radiation Probing, Gauging, Imaging and Analysis: Volume I Basics and Techniques (Non-Destructive Evaluation Series), Springer; 1 edition (May 31, 2003)]. FIG. 12 shows the range R of an energetic electron in a-Si:H versus the kinetic energy of the electron.

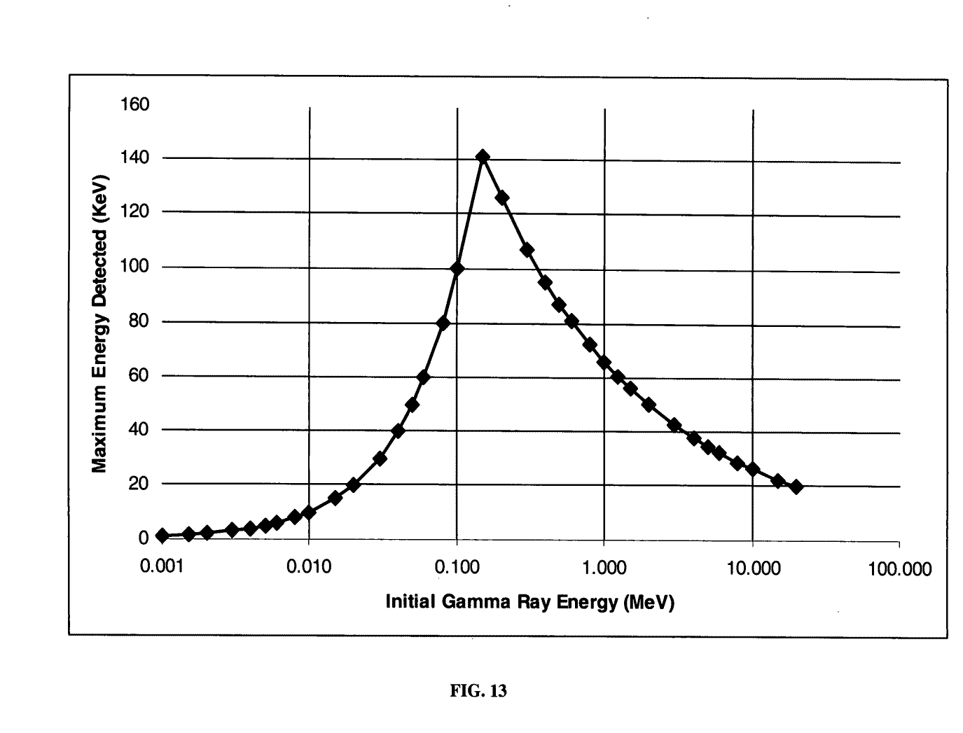

The upper limit of the gamma energy absorbed in our preferred neutron detector (five ¹⁰B layers with adjacent a-Si:H diodes) can be calculated, assuming that the absorbed gamma photon imparts all of its energy in a single event, thereby liberating an energetic electron (beta particle) in the diode stack. FIG. 13 shows a graph of the energy deposited in a twenty-two ¹⁰B layer neutron detector by an energetic electron that is liberated from the absorption of an incident gamma photon, calculated versus the incident energy of the gamma photon. The maximum energy deposited in the stack by a gamma-produced energetic electron is 140 KeV for a 150 KeV gamma photon. Setting the lower level discriminator (LLD) to exclude the 300 KeV events should provide the commonly specified <10⁴ gamma insensitivity requirement, defined as the ratio of neutron detector's gamma photon detection efficiency to the intrinsic efficiency for detecting neutrons, while leaving headroom for detection of the 1.47 MeV alpha and/or 840 KeV lithium particles resulting from the neutron absorption.

### Other Preferred Embodiments

### Ten and Fifteen Layer ¹¹° B Layer Neutron Detector

A second preferred embodiment of the thermal neutron detector, displayed in FIG. 5, has ten ¹⁰B layers. Two of the above five-layer detectors can be physically stacked to produce a neutron detector with ten ¹⁰B layers interleaved with twelve a-Si:H diodes and FIG. 6 shows that this combined device has an intrinsic efficiency of 55 percent for detecting thermal neutrons compared to 34 percent for the five layer detector. Three of the preferred detectors can be physically stacked to produce a neutron detector with fifteen ¹⁰B layers interleaved with eighteen a-Si:H diodes and FIG. 6 shows that this combined device has an intrinsic efficiency of 70 percent for detecting thermal neutrons.

### Fabrication Techniques

The neutron detectors can be fabricated using thin-film deposition techniques developed for solar cell and/or thin-film transistor (TFT) fabrication. The primary detector component, the stacked ¹⁰B-layer/a-Si:H diode stack, can be manufactured at a dedicated amorphous silicon solar cell foundry or TFT foundry. The neutron detector can be fabricated as a single monolithic semiconductor stack in sizes up to the present limit of solar cell manufacturing technology (˜1 m²). These foundries also possess techniques and equipment for electrically dividing the large areas into the smaller areas required for specified neutron counting rates, as well as inter-connect technology to electrically connect the smaller area detectors to external counting/discrimination circuitry. This will enable large area, high performance neutron detectors to be manufactured at relatively low cost.

### Fast Neutron Detection

Fast neutrons (>1 eV) present a much smaller capture cross section than thermal neutrons (<1 eV) and thus capture efficiency drops dramatically with energy. Thus fast neutrons are nearly invisible to the preferred embodiment of the neutron detector. The energy of fast neutrons can be reduced to that of thermal neutrons by passing the neutrons through a neutron moderator material such as graphite or high density polyethylene (HDPE). A moderator consists of a material with light nuclei that reduce the neutron energy through elastic collisions while presenting a small capture cross section so that the neutron is not absorbed.

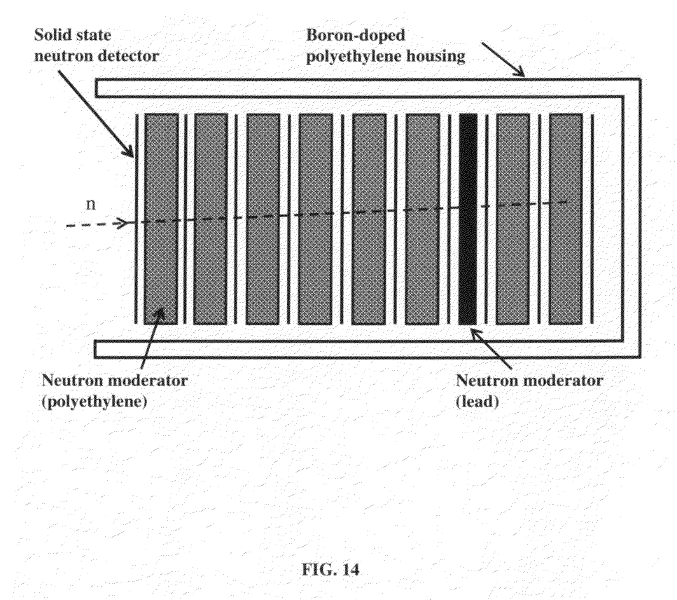

FIG. 14 shows a neutron spectrometer that interleaves neutron moderator material with the Applicant's thermal neutron detector. A stack of multiple a-Si:H neutron detectors separated by HDPE layers will enable the detection of thermal neutrons from the top detector and fast neutrons with increasing energy from subsequent detectors. This detector structure will enable the extraction of neutron energy spectra by unfolding the pulse height spectra of the detector layers. The resolution may be optimized by adjusting the moderator layers and the range determined by the number of moderator/detector pairs.

### Variations

Although the present invention has been described above in terms of preferred embodiments, persons skilled in this art will recognize there are many changes and variations that are possible within the basic concepts of the invention. For example, neutrons interact with several other isotopes to produce neutron-alpha reactions. To the extent these isotopes can be incorporated into a solid material they could replace the boron-10 described in the preferred embodiments. Also neutrons interact with other isotopes to produce neutron-proton reactions. Replacing boron 10 with these isotopes would permit the high energy protons to be detected in the a-Si:H diodes. The boron 10 isotope could be replaced by fissionable material such as U-235 in which case fission products would be detected in the aSi:H diodes.

The thickness of the layers can be varied based on considerations such as cost, efficiency, energy of the ionizing particles and other considerations. The a-Si:H layers, for boron-10 alpha particles, will typically have thicknesses of less than 10 microns, preferably between 2 and 10 microns. The neutron absorbing layers for boron may be adjusted based on the degree of enrichment in boron 10, but typically will be less than 10 microns and preferably will range between 1 and 3 microns. When utilizing materials other than boron as the neutron absorber, the thickness will probably need to be adjusted accordingly based on the issues discussed with respect to the specific preferred embodiments.

Therefore the reader should determine the scope of the present invention by the appended claims and not by the specific examples described above.

We claim:

1. A low-cost device for the detection of neutrons comprising:
A) a multi-layer structure comprising:
1) a plurality of thin layers of a material chosen for high absorption of neutrons with a corresponding release of ionizing particles interleaved with
2) a plurality of thin layers of hydrogenated amorphous silicon PIN diodes,
3) an electrical circuit adapted to connect at least a portion of the PIN diode layers in parallel;
wherein neutrons passing into the multi-layer structure are absorbed in the neutron absorbing material producing neutron reactions with the release of high energy ionizing particles which create electron-hole pairs in the PIN diode layers that are detected by the electrical circuit.

2. The device as in claim 1 wherein at least some of the plurality of thin layers of a material chosen for high absorption of neutrons with a corresponding release of ionizing particles are comprised of boron.

3. The device as in claim 2 wherein the boron is enriched in boron-10 isotopes.

4. The device as in claim 2 wherein at least some of the plurality of thin layers of a material chosen for high absorption of neutrons with a corresponding release of ionizing particles have thicknesses in the range of 1 to 3 microns.

5. The device as in claim 2 wherein at least some of the thin layers of hydrogenated amorphous silicon PIN diodes have thicknesses of between 2 and 10 microns.

6. The device as in claim 1 wherein the ionizing particles comprise alpha particles.

7. The device as in claim 1 wherein the ionizing particles comprise protons.

8. The device as in claim 1 wherein the ionizing particles comprise fission products.

9. The device as in claim 1 wherein each of the two pluralities of thin layers is at least five thin layers.

10. The device as in claim 1 wherein each of the two pluralities of thin layers is at least ten thin layers.

11. The device as in claim 1 wherein each of the two pluralities of thin layers is at least fifteen thin layers.

12. The device as in claim 1 wherein each of the two pluralities of thin layers is at least five twenty-two layers.
